(19) United States
(12) Patent Application Publication
(10) Pub. No.: US 2006/0266639 A1
(43) Pub. Date: Nov. 30, 2006

(54) Sputtering target tiles having structured edges separated by a gap

(75) Inventors: Hien-Minh Huu Le, San Jose, CA (US); Bradley O. Stimson, Monte Sereno, CA (US); Akihiro Hosokawa, Cupertino, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/414,016

(22) Filed: Apr. 28, 2006

Related U.S. Application Data
(63) Continuation-in-part of application No. 11/137,262, filed on May 24, 2005.

(51) Int. Cl. C23C 14/32; C23C 14/00

(52) U.S. Cl. 204/192.1; 204/298.12

(57) ABSTRACT

A target assembly composed of multiple target tiles bonded in an array to a backing plate of another material. The edges of the tile within the interior of the array are formed with complementary structure edges to form a gap between the tiles having at least a portion that is inclined to the target normal. The gap may be simply beveled and slant at an angle of between 10° and 55°, preferably 15° and 50°, with respect to the target normal or they may be convolute with one portion horizontal or otherwise inclined to prevent a line of sight from the bottom to top. The area of the backing plate underlying the gap may be coated or overlain with a foil of the material of the target, for both perpendicular and sloping gaps, and have a polymeric foil adjacent an elastomeric bonding layer to exclude bonding material from the gap.

### RELATED APPLICATION

This application is a continuation in part of Ser. No. 11/137,262, filed May 24, 2005.

### FIELD OF THE INVENTION

The invention relates generally to sputtering of materials. In particular, the invention relates to sputtering targets composed of multiple tiles.

### BACKGROUND ART

Sputtering, alternatively called physical vapor deposition (PVD), is the most prevalent method of depositing layers of metals and related materials in the fabrication of semiconductor integrated circuits. Sputtering is now being applied to the fabrication of flat panel displays (FPDs) based upon thin film transistors (TFTs). FPDs are typically fabricated on thin rectangular sheets of glass. A layer of silicon is deposited on the glass panel and silicon transistors are formed in and around the silicon layer by techniques well known in the fabrication of electronic integrated circuits. The electronic circuitry formed on the glass panel is used to drive optical circuitry, such as liquid crystal displays (LCDs), organic LEDs (OLEDs), or plasma displays subsequently mounted on or formed in the glass panel. Yet other types of flat panel displays are based upon organic light emitting diodes (OLEDs). Other types of substrates are being contemplated, for example, flexible polymeric sheets. Similar techniques can be used in fabricating solar cells.

Size constitutes one of the most apparent differences between electronic integrated circuits and flat panel displays and in the two sets of equipment used to fabricate them. Demaray et al. disclose many of the distinctive features of flat panel sputtering apparatus in U.S. Pat. No. 6,199,259, incorporated herein by reference. That equipment was originally designed for panels having a size of approximately 400 mm×600 mm. Because of the increasing sizes of flat panel displays being produced and the economy of scale realized when multiple displays are fabricated on a single glass panel and thereafter diced, the size of the panels has been continually increasing. Flat panel fabrication equipment is commercially available for sputtering onto substrates having a minimum size of 1.8 m and equipment is being contemplated for panels having sizes of 2 m×2 m and even larger, that is, substrates having an area of 40,000 cm² or larger.

For many reasons, the target for flat panel sputtering is usually formed of a sputtering layer of the target material bonded to a target backing plate, typically formed of titanium. The conventional method of bonding a target layer to a backing plate applies a bonding layer of indium to one of the two sheet-like members and presses them together at a temperature above indium's melting point of 156° C. A more recently developed method of bonding uses a conductive elastomer or other organic adhesive that can be applied at much lower temperatures and can be typically cured at an elevated but relatively low temperature, for example, 50° C. Such elastomeric bonding services are available from Thermal Conductive Bonding, Inc. of San Jose, Calif. Demaray et al. in the aforecited patent disclose autoclave bonding.

### SUMMARY OF THE INVENTION

According to one aspect of the invention, multiple target tiles are bonded to a backing plate with a structured gap formed between complementary structured edges of adjacent target tiles.

In one set of embodiments, the gap is slanted between complementary beveled edges of the target tiles. The edges may slope at angle in range between 10° and 55°, preferably between 15° and 45° or 50° with respect to the normal of the front surfaces of the target tiles. A tile edge at the outer periphery of the array of bonded target tiles may be formed with a beveled edge slanting outwardly toward the center of the tiles.

In another set of embodiments, the gap is convolute, for example, and provides no line of sight between the bottom and top of the target tiles. In one embodiment one or more portions of the gap may be slanted and an intermediate part is horizontal with respect to the tile surfaces or at least inclined with respect to the slanted portions to form a convolute gap. In another embodiment, the gap is formed of three rectilinear portions parallel to and perpendicular to the tile surface. The corners connecting neighboring sections of the gap may be curved. The tile edges are structured to produce the desired gap.

According to another aspect of the invention, the structured or beveled edges of the tiles may be roughened by bead blasting for example.

According to yet another aspect of the invention, the portion of the backing plate at the bottom of a gap separating two target tiles may be selectively roughened while leaving a principal part of the backing plate underlying the tiles smooth and in contact with the tiles.

According to a further aspect of the invention, the portion of the backing plate at the bottom of the inter-tile gap may be coated with a layer of target material or a strip of target material may be laid on the bottom prior to tile bonding.

In the case of elastomeric tile bonding, a polymeric tape may placed between the foil strip and the planar elastomeric layer. Such a tape advantageously prevents the elastomeric material from flowing into the gap during bonding and curing. If a foil is not used, the polymeric tape is placed between the elastomeric bonding layer and the tiles in the area of the gap. The foil or polymeric tape may be applied to target tiles not having structured edges.

### BRIEF DESCRIPTION OF THE DRAWINGS

FIG. 1 is a schematic cross-sectional view of a conventional plasma sputter reactor adapted for sputter deposition onto rectangular substrates.

FIG. 2 is a plan view of conventional sputtering target composed of multiple target tiles bonded to a backing plate.

FIG. 3 is a cross-sectional view of a portion of a sputter target of the invention including two target tiles separated by a slanted gap.

FIG. 4 is a cross-sectional view of a beveled peripheral portion of a target tile.

FIG. 5. is a cross-sectional view of a portion of a sputter target of the invention including either a roughened portion of the backing plate or a region of target material coated on a area of the backing plate at the bottom of the gap between two tiles. The figure also shows roughening of the two beveled edges of the target tiles.

FIG. 6 is a cross-sectional view of a portion of the sputter target including a foil strip of target material underlying the gap.

FIG. 7 is a cross-sectional view illustrating the accumulation of redeposited material on the sidewalls of a slanted gap in the target of FIG. 6.

FIG. 8 is a cross-sectional view of an embodiment of the invention including a inclined and stepped gap between tiles of the target.

FIG. 9 is a plan view of some of the magnets forming the serpentine plasma loop.

FIG. 10 is a cross-sectional view of a variant embodiment of the embodiment of FIG. 8 including a vertical lower portion of the gap.

FIG. 11 is a cross-sectional view of a curved variant of the embodiment of FIG. 10 including curved corners in the inter-tile gap.

FIG. 12 is a cross-sectional view of another embodiment of the invention in which complementary structured edges of the tiles for a stepped rectilinear gap.

### DETAILED DESCRIPTION OF THE PREFERRED EMBODIMENTS

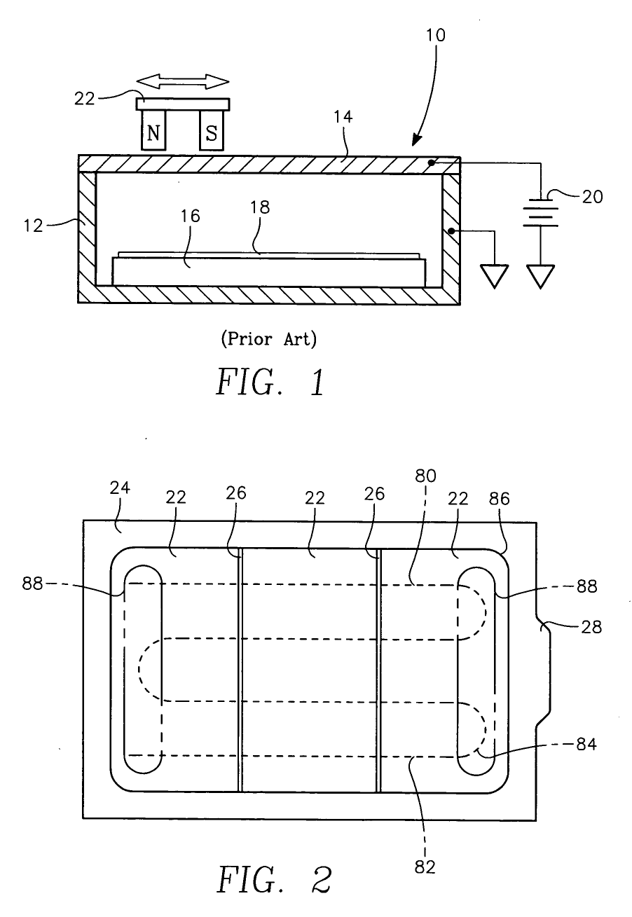

A sputtering chamber 10, schematically illustrated in the cross-sectional view of FIG. 1, includes a vacuum chamber 12, a target 14 sealed to but electrically isolated from the electrically grounded chamber 12, and a pedestal 16 supporting a panel 18 to be sputter coated. The target 14 includes a surface layer of the material to be sputtered onto the panel 18. An argon working gas is admitted into the chamber with a pressure in the milliTorr range. A power supply 20 electrically biases the target 14 to a negative voltage of a few hundred volts, causing the argon gas to discharge into a plasma. The positive argon ions are attracted to the negatively biased target 14 and sputter target atoms from it. In many applications, a magnetron 22 is scanned over the back of the target to intensify the plasma and increase the sputtering rate. Some of the target atoms strike the panel 18 and form a thin film of the target atoms on its surface. The target 14 is often somewhat larger than the panel 18 being sputter coated. However, in some sputter reactors such as in-line sputter chambers, the target is smaller. Sputtering for flat panels has utilized a large number of target materials including aluminum, copper, titanium, tantalum, molybdenum, chromium, and indium tin oxide (ITO) as well as other materials.

One problem arising from the increased panel sizes and hence increased target sizes is the difficulty of obtaining target material of proper quality in the larger sizes. Refractory materials such as chromium or molybdenum are particularly difficult materials. The size problem has been addressed by forming the target sputtering layer from multiple target tiles. As schematically illustrated in the plan view of FIG. 2, multiple target tiles 22 are set on a backing plate 24 with a predetermined gap 26 between them. The tiles 22 are thereafter bonded to the backing plate 24. The large peripheral area of the backing plate 24 outside the tiles 22 is used to support the target 14 on the vacuum chamber 12 and one or more extensions 28 of the backing plate 24 extend outside of the outline of the vacuum chamber 12 to provide plumbing ports for the water cooling channels formed in the backing plate 24 and electrical connect to the bias source. Although not illustrated here, the magnetron 22 is typically located with another vacuum chamber at the back of the target 14 so as to reduce the differential pressure across the large target 14, which needs to be relatively thin to allow the magnetic field to effectively penetrate to the front of the target 14.

The arrangement of three tiles illustrated in FIG. 2 represents a simple one-dimensional array, although the number may be two or greater than three. Demaray in the aforecited patent discloses a larger number N>2 of tiles in a linear array with (N−1) gaps between them. Tepman describes both one-dimensional arrays and a two-dimensional array of tiles with vertical and horizontally extending gaps intersecting each other in U.S. patent application Ser. No. 10/888,383, filed Jul. 9, 2004, published as U.S. Patent Application Publication 2006/0006058-A1 and Ser. No. 11/158,270, filed May 21, 2005, both applications incorporated herein by reference. The two-dimensional array may be a rectangular array, a staggered array as in simple brick wall, or more complicated two-dimensional arrays including herringbone patterns. Although rectangular tiles present the simplest geometry, other tile shapes are possible, such as triangular and hexagonal tile shapes with correspondingly more complex gap arrangements. However, in many applications a one-dimensional array is sufficient.

The gaps 26 between tiles must be carefully designed and maintained. Typically, the gap is not filled with other material, and conventionally the adhesive or material other than the target material is exposed at the bottom of the gap 26. However, if the gap (or at least part of it) is maintained at less than about 0.5 to 1.0 mm, then the sputtering plasma cannot propagate into the gap because the gap is less than the plasma dark space. With no plasma propagating to the bottom of the gap, the backing plate is not sputtered. However, there is a tendency for the material sputtered from the target tiles to be redeposited on the target tiles. Usually this is not a problem because the redeposited material is again sputtered at a rate faster than it is being deposited, thereby avoiding the problem of a thick layer accumulating composed of redeposited material of less than optimal quality. That is, the top tile surfaces are kept clean. However, the sputtered material is also redeposited into the gaps between the tiles although at a reduced rate because of the geometry. However, since the plasma does not extend significantly into the gap in a well operated target, the resputtered material is not again sputtered at a rate as high as on the planar surface of the tiles. That is, the redeposited material tends to accumulate to a significant thickness on the sides and bottom of the gap. Redeposited material tends to peel and flake if allowed to accumulate to a substantial thickness. The flaking material form particles on the order of dust which, if they fall on the panel or other substrate being sputter coated, are likely to cause a defect in the electronic circuitry being developed in the panel. One method of reducing the redeposition and resultant flaking is to reduce the width of the gap, for example, to between 0.3 and 0.5 mm. Attempts to further reduce the gap to 0.1 mm introduce operational difficulties encountered in fabricating the target assembly and in maintaining the gap during temperature cycling.

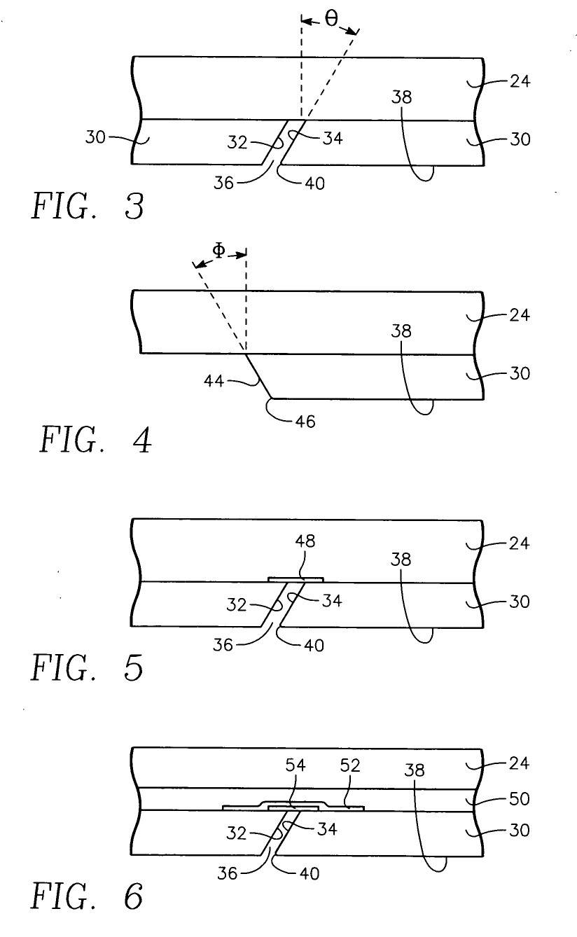

One embodiment of the invention is illustrated in the cross-sectional view of FIG. 3, target tiles 30, typically of a common composition, are bonded to the backing plate 24, which is typically composed of a different material, often titanium. The bonding of the tiles 30 to may be achieved, for example, by a thin layer of adhesive or a metal such as indium having a low melting temperature. The backing plate 24 is sometimes formed of multiple layers and to include cooling channels to keep the target cool during sputter operation. However, in other applications, the backing plate is an integral member cooled by other means.

According to one aspect of the invention, adjacent tiles 30 are slanted at complementary angles on opposed sides 32, 34 separated by a slanted gap 36 that is inclined with respect to the normal of front faces 38 of the tiles 30, for example at an angle θ of between 10° and 55°, preferably between 15° and 45° or 50° from the normal of the front faces 38 of the tiles 30. An angle of 45° is often used in practice. The thickness of the gap 36 in the direction perpendicular to the slanting sides 32, 34 may be maintained at 0.3 to 0.5 mm. The tiles edges or sides 32, 34 may be characterized as having complementary structure, that is, not simply perpendicular to the tile faces 38 with a substantially constant gap 36 between the tile sides 32, 34 over a substantial portion of the gap 36. Complementary structured edges do not include edges that are merely rounded at their corners, for example, in the same mirrored but not complementary profile.

The slanting provides at least two benefits. Any redeposited material that flakes from sides 32, 34 of the slanted gap 36 is either already on a lower tile surface 34 in the operational position and gravity tends to hold the flakes there or the flakes fall from an upper tile surface 32 towards the lower tile surface 34, which tends to hold them there. The latter mechanism, however, does not apply to a narrow region near the front face 38. Furthermore, the total length of the gap 36 between the principal sputtering surface 38 of the tiles 30 and the backing plate 24 is increased. Thereby, the plasma is kept further away from the backing plate 24. Other angles θ enjoy benefits of the invention. However, a lesser angle θ reduces both beneficial results described above and a greater angle θ is somewhat more difficult to work with because of substantial overlap and acute corners. The acute corners can be formed as somewhat rounded corners 40, but rounding detracts from both beneficial results. A yet further beneficial effect is that while the slanted gap thickness may be maintained at 0.3 to 0.5 mm with full effect on the plasma dark space, the gap thickness along the direction of the planar faces is greater by a factor of the co-tangent of θ, thus easing assembly and movement problems.

Advantageously, according to another aspect of the invention, the opposed sides 32, 34 of the tiles 30 are bead blasted or otherwise roughened, preferably prior to bonding. As a result, any sputter material redeposited on the opposed sides 32, 34 adheres better to the sides 32, 34 of the tiles 30 to reduce or delay the flaking. The bead blasting may be performed by entraining hard particles, for example, of silica or silicon carbide, in a high pressure gas flow directed at the tile to roughen its surface, for example, to a roughness of 300 to 500 microinches.

On the other hand, the external peripheral edges of the tiles 30, that is, the edges not facing another tile 30 across a gap 36, are preferably tapered as illustrated in the cross-sectional view of FIG. 4 to form a sidewall 44 that tapers inwardly away from the backing plate 24 at an angle φ before joining the front face 38 of the tile 30 through a with a curved corner 46. The angle φ may be in a range of 10° to 55°, preferably near 15°. In use, the slanting sidewall 44 is spaced from a similarly shaped dark-space shield attached to the chamber by a small gap that prevents the plasma from propagating to the uncovered backing plate 24.

Preferably, the sidewall 44 is bead blasted, prior to bonding to the backing plate 24, to promote adhesion of redeposited material. Thereby, what material is redeposited on the tapered sidewall 44 is more solidly attached to it to thereby reduce flaking of the redeposited material and the resultant particulates.

In a related aspect of the invention, as illustrated in the cross-sectional view of FIG. 5, the backing plate 24 is bead blasted prior to tile bonding in a region 48 over which the gap 36 will develop after tile bonding. Contrary to the illustration, the bead blasting forms a roughened surface with some sub-surface damage confined very close to the surface. The roughening of the tile edges adjacent the gap is applicable to perpendicular as well as to slanted tiles edges and gaps. Preferably, the majority of the area of the backing plate 24 facing the tiles 30 is left substantially smoother than the roughened region 48 so that the tiles 30 can be bonded more intimately with the backing plate 24 if a surface adhesive layer is used or be directly contacting the smooth area of the backing plate 24 if the adhesive is filled into recesses in the backing plate 24. The surface roughening is applicable to other structured tile edges described in the embodiments below.

In a yet further aspect of the invention, prior to bonding of the tiles 30 to the backing plate 24, target material is deposited in the region 48 over which the gap 36 will develop after tile bonding. A strip of target material may be bonded to the backing plate 24 to form the region 48, for example, with a polymeric adhesive. The thickness of the strips may be in a range between 1 and 4 mm. In one embodiment, the region 48 is machined as a recess into the backing plate 24 and target material is selectively deposited into the recess. Thereby, if some sputtering does occur at the bottom (top as illustrated) of the gap 36, for example, during arcing or plasma striking, target material of the region 48 rather than material of the backing plate 24 is sputtered. This feature is useful for perpendicular as well as slanted or otherwise structured gaps. The additional target material 48 beneath the gap 36 or bead blasting of the backing plate 24 is particularly advantageous when the adhesive bonding the tiles 30 to the backing plate 24 is patterned and does not extend into the area of the gap 36. That is, adhesive is not exposed at the bottom of the gap 36. Instead, either the roughened region 44 of the backing plate or the region 44 of the target material is exposed. The roughening of the backing plate 24 or the target material deposited or laid on the backing plate 24 at the bottom of the gap 36 is applicable to perpendicular as well as slanted gaps.

Another embodiment, illustrated in the cross-sectional view of FIG. 6, includes a planar elastomeric bonding layer 50, typically composed or an organic polymer, which is applied to the backing plate 24 in an uncured and flowable state and which is cured at a relatively low temperature, for example, 50° C. by the method described in the background section. A thin flexible polymeric tape 52, such as Kapton® tape composed of polyimide and available from DuPont, is laid over the bonding layer 50 in the area of the intended tile gap 36. Kapton tape has the advantage of maintaining its integrity at elevated temperatures of over 350° C. Note that the vertical orientation during the bonding is inverted from the operational orientation illustrated in FIG. 6. The tape 52 may be very thin and relatively narrow, for example, about 1 cm wide. It need not include any adhesive. A foil strip 54 of the target material is laid over the polymeric tape in the area of the intended gap. The foil strip 54 is relatively thin and flexible, for example, between 0.1 and 0.5 mm thick and have a width somewhat greater than that of in the intended gap 36. The target tiles 30 are then laid over the bonding layer 50 with the gap 36 aligned with the foil strip 54. Moderate pressure and temperature are applied to assembly to flow and cure the bonding layer 50 to conform to the tile shape and the additional thicknesses of the polymeric tape 52 and foil strip 54 and to bond the tiles 30 to the backing plate 24. The polymeric tape 52, which bonds well to the polymeric bonding layer 50 while it does not itself flow, prevents the polymeric and elastomeric bonding material from flowing into the gap 36 and interfering with the sputtering process.

The use of the foil strip 54 is not limited to target tiles with structured edges but may be used with tiles having vertical edges and forming a vertical gap. The foil strip 54 also provides similar advantages for other types of tile bonding. Also, the use of the polymeric tape 52 is not limited to target tiles with structured edges or to be used in conjunction with the foil strip. Whenever elastomeric tile bonding is used, the polymeric tape 52 effectively excludes the elastomer having a higher melting or curing temperature from penetrating into the gap and interfering with sputtering.

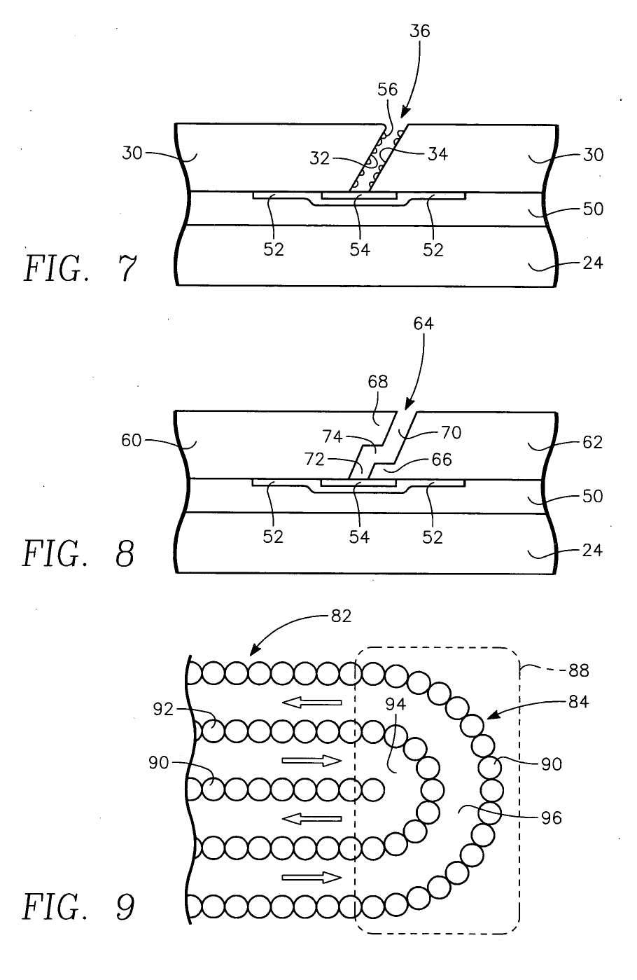

The target structure of FIG. 6 has been shown to be easily fabricated and to sputter deposit high-quality films. However, it has exhibited some operational drawbacks. As shown in the cross-sectional view of the target structure in FIG. 7, which is illustrated in the fabricational and maintenance orientation, when molybdenum is being sputtered to form silicide contacts, some of the sputtered molybdenum is redeposited on the gap sidewalls 32, 34 as molybdenum-based globules 56 or layers. The redeposited material does adhere well to the underlying mobybdenum tiles 30 and, beyond a certain threshold thickness, it tends to flake off from the tiles 30 and form large particles. Despite the angle of the gap 36, the large particles can fall onto the panel substrate being sputter deposited and form defects on the panel. Some defects may result in an inoperative pixel in a display while others may short out electrical lines rendering at least part of the panel to be inoperative. That is, the redeposited material decreases yield if left to build up. Although molybdenum seems to present a particular problem because of its refractory nature, target redeposition occurs with most sputtered materials and the threshold thickness before flaking occurs varies between the materials. Hence, though our description will use molybdenum as the material being sputtered, it applies equally well to other target materials including the common composition of the associated foil strip 54.

One method of preventing such particle contamination is to periodically physically clean the target and remove the redeposited molybdenum 52 from the gaps 36. One type of cleaning involves rubbing sand paper along the gap sidewalls 32, 34 to loosen the redeposited molybdenum, which is then blown or rinsed out of the gaps 36 and away from the target. However, sanding inside the narrow gap 36 is difficult and the technician is likely to damage the molybdenum foil strip 54 at the bottom of the gap 36 and the associated polymeric tape 52. Even a small pinhole through the molybdenum foil strip 54 exposes the underlying polymeric material, which tends to be very soft, to some ion bombardment in the sputtering process. As a result, organic polymeric material as well as molybdenum is likely to be deposited if the molybdenum foil strip 54 has been breached.

A further problem arises as the target tile is consumed during sputtering so that the thickness of the tile decreases and the aspect ratio of the gap 36 decreases, that is, the ratio of depth to width of the gap 36 decreases. The decreased aspect ratio increases the viewing angle of the molybdenum foil strip 54 out of the gap 36 such that the foil strip 54 is exposed to a higher flux of high-energy argon ions from the plasma outside of the gap 36. The increased ion bombardment can damage and penetrate the molybdenum foil strip 54 and expose the underlying organic material.

In another aspect of the invention, as illustrated in the cross-sectional view of FIG. 8, the tiles 60, 62 are formed with internal facing edges having complementary structures forming a stepped slanted gap 64. One tile 62 is formed with a step 66 on its bottom and the other tile 60 is formed with an overhang 68 on its top. The gap 64 includes a slanted upper portion 70, a slanted bottom portion 72, connected by a horizontal passageway 74 formed between the step 66 and the overhang 68. The width of the step 66 should be at least as large as the horizontal width of the upper portion of the gap 64 such that the horizontal passageway 74 may be more functional than physical. The width of the gap 64 may vary between its portions 60, 72, 74 but at least the upper and bottom portions 70, 72 may have substantially constants widths along their respective lengths. Exemplary dimensions for the tiles 60, 60 having thickness of between 10 and 13 mm are that the gaps 64 have horizontal widths of between 05 and 1 mm, the step 66 has a thickness of about 2 mm, and the bottom of the overhang 68 is about 3 mm above the bottom of the tile 62. The opposed tile edges have complementary structure typically producing a gap width that is constant in the different portions of the gap 64 although there width may vary between the different portions0. In general, the bottom of the overhang 68 is in the lower half and preferably lower third of the uneroded tile 60 with the step 66 being located below it by a suitable finite gap.

This stepped edge structure has several advantages. It is almost impossible for the technician sanding away redeposited molybdenum from the upper part of the gap 64 to damage the foil strip 54 at the bottom of the lower part of the gap 64. Because the stepped gap 64 presents a convolute path between the sputtering plasma and the lower portion 72 of the gap 64, very little molybdenum is redeposited on the sidewalls in the lower portion 72 of the gap 64 or on the foil strip 54. The convolute path of the gap 64 also prevents any line of sight between the foil strip 54 and the sputtering plasma, thus preventing any ion bombardment of the molybdenum foil strip 54. This blocking of the line of sight continues even as the tile thickness decreases after prolonged sputtering and the aspect ratio of the upper portion 70 of the gap 64 decreases. As a result, the molybdenum barrier 54 at the bottom of the gap 54 is not likely to be breached and to expose the underlying organic material.

Of course, the protection of the stepped gap 64 disappears when target erosion has progressed to the point that the overhang 68 disappears. As a result, the target needs to be replaced before the overhang 68 is eroded through, for example, before the bottom 3 mm of the target tiles 60, 62 in the area of the gap 64 with the above exemplary gap dimensions are sputtered. However, it is possible that the invention can be practiced without sacrificing target utilization. Returning to FIG. 2, the target tiles 22 may be scanned over relatively short distances by a magnetron forming a closed plasma loop that is folded to form a serpentine plasma loop 80 having straight sections 82 joined by rounded ends 84. The serpentine plasma loop 80 is formed, as illustrated in the plan view of FIG. 9, by two sets of magnets 90, 92 of opposite polarities arranged in closely spaced rows with gaps 94, 96 between them forming anti-parallel plasma tracks on the sputtering faces of the tiles 22 of the target 14. One set of magnets 90 forms an outer pole of one polarity surrounding an inner pole of the other polarity formed by the other set of magnets 92. The magnets 90, 92 are arranged predominantly in the straight sections 82 over most of the target 14 but in the rounded ends 84 near the target edge. The illustrated structure is not completely accurate and the Tepman reference should be consulted for a more accurate structure in which each track is bracketed between dedicated rows of anti-parallel magnets so that the magnets are arranged in adjacent rows over most of the interior of the magnetron.

Returning to FIG. 2, rounded exterior corners 86 of the tiles 22 follow similarly rounded corners in the plasma track. Such a serpentine magnetron if typically scanned over relatively short distances in two dimensions to even out the erosion pattern, as has been described by Tepman in U.S. patent application Ser. No. 10/863,152, filed Jun. 7, 2004 and published as Patent Application Publication 2005/0145478-A1 and U.S. patent application Ser. No. 11/211,141, filed Aug. 24, 2005 and published as Patent Application Publication 2006/0049040-A1, both incorporated herein by reference. The scanned sputtering nonetheless has been observed to produce two edge regions 88 of high erosion rate generally overlying the loop's rounded ends 84. A 10 mm target has been observed to sputter 2 mm more in the edge regions 88 than at the target center, which is approximately the unused tile thickness around the stepped gap 64 of FIG. 8. A target is exhausted when the edge regions 88 have been eroded through. If the straight sections 82 of the plasma loop 80 are arranged to be perpendicular to the inter-tile gaps 26 in a one-dimensional array of tiles, the extra erosion occurs at a distance from the gaps 26 so that the edge regions 88 are eroded away at just about the same time as the overhangs 68 are eroded away.

It is also appreciated that the stepped and overlapping tile edges do not affect the tile bonding process. This aspect of the invention is also applicable to other forms of tile bonding and does not depend upon the use of foil strips.

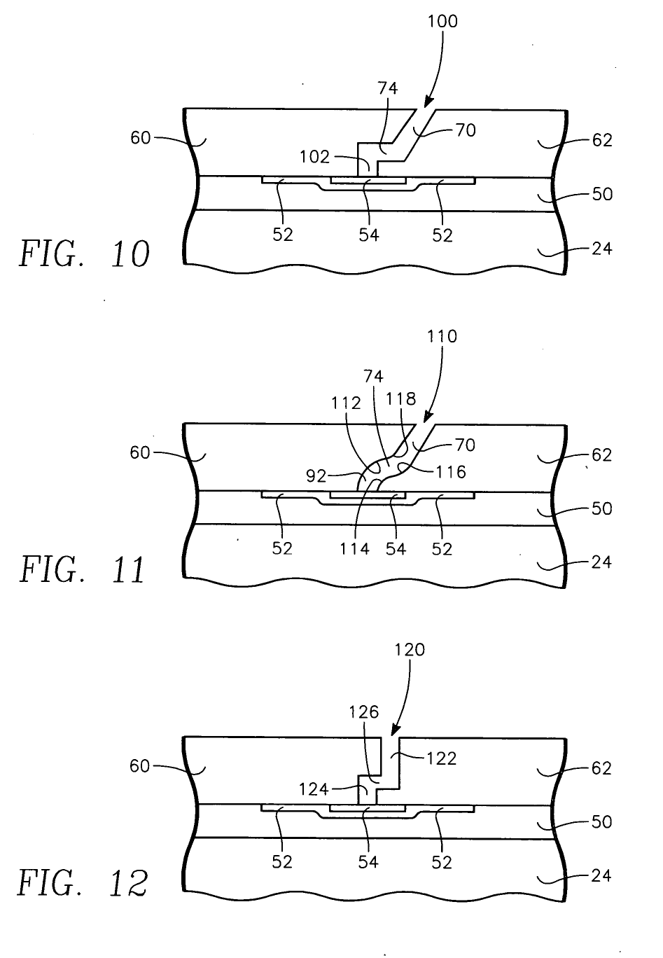

The shape of the gap and stepped edge can be varied. The step top and the overhang bottom need not be horizontal but may be inclined as long as they present a convolute passageway between the two principle faces of the target tiles. For example, in the tile structure of FIG. 10, a gap 100 is formed from the slanted upper gap 70 and the horizontal passageway 74, but a lower gap 102 is vertical. Such a structure may simplify the machining of the tile edges.

Many ceramic materials and even some refractory materials to be used as sputtering targets are difficult to machine, especially into the sharply angular shapes described in the previous embodiments. These embodiments can be modified to provide more curved corners between the portions of a convolute gap. For example, the embodiment of the invention illustrated in cross section in FIG. 11 includes a convolute gap 110 similar to the stepped gap 100 of FIG. 10 but having curved corners 112, 114, 116, 118 connecting the gap portions 70, 74, 92. Such a structure is more easily machined without danger of fracturing. The horizontal passageway 74 should be somewhat longer, however, to prevent a line of sight from the foil strip 54 to the plasma as the tiles 60, 62 are eroded. The horizontal passageway 74 may be somewhat inclined as illustrated or be strictly horizontal.

A stepped gap between tiles also provides some of the same advantages of the slanted gap. Accordingly, another embodiment, illustrated in cross section in FIG. 12 includes a stepped rectilinear gap 120 between the tiles 60, 62 including a vertical upper portion 122 and a vertical lower portion 124 connected by a horizontal passageway 126. That is, neighboring sections of the gap 120 are perpendicular to each other. This embodiment may be characterized as having the two tiles 60, 62 being lapped together. The stepped gap 120 prevents any line of sight between the foil strip 54 for damaging energetic plasma ions and the plasma. The decreasing aspect ratio of the upper portion 122 after extended erosion does not affect the lack of line of sight. The structure also prevents sanding damage to the foil strip 54. However, in its operational orientation, the vertical structure does not tend to gather loose particles as they fall towards the panel.

The above embodiments have been explained in the context of a linear array of target tiles. Most of the aspects of the invention may be applied to two-dimensional arrays, but the embodiments including steps tend to experience decreased target utilization when applied to two-dimension arrays.

Many of the embodiments have been described with reference to molybdenum targets, but other target materials may be substituted.

The aspect of the invention involving complementary beveled tile edges is applicable to sputtering in virtually any application in which the target includes multiple target tiles mounted on a backing plate, for example, for sputtering onto solar cell panels. It can be applied as well to sputtering onto circular wafers in which a generally circular target is composed of multiple tiles, for example, of segmented shape or arc shape surrounding a circular center tile. The invention can be applied to cluster tool systems, in-line systems, stand-alone systems or other systems requiring one or more sputter reactors.

Thus the invention can reduce the production of particulates and of extraneous sputtered material with little increase in cost and complexity of the target, particularly, a multi-tile target.

1. A set of tiles to be arranged in an array to form a sputtering target, wherein adjacent edges of neighboring tiles in the array have complementary structured edges to form a predetermined gap between the neighboring tiles which has at least a central portion thereof which is inclined to a normal of the tiles in the array.

2. The set of claim 1, wherein the edges are beveled at a predetermined angle so that the gap slants at said angle between principal surfaces of the tiles.

3. The set of claim 1, wherein the edges have a stepped structure so that the gap is convolute between the principal surfaces of the tiles and presents no line of sight between planes of the principal surfaces.

4. The set of claim 3, wherein the convolute gap includes two slanted portions joined by a portion parallel to the principal surfaces.

5. The set of claim 3, wherein the convolute gap includes three rectilinear portions.

6. A sputtering target, comprising:
a backing plate; and
an array sputtering tiles bonded to the backing plate in an array, wherein adjacent edges of neighboring tiles in the array have complementary structured edges to form a predetermined gap between the neighboring tiles which has at least a central portion thereof which is inclined to a normal of the principal surfaces of the tiles in the array.

7. The target of claim 6, wherein the edges are formed at an inclined angle with respect to the normal to form the gap as a slanted gap extending between the principal surfaces of the tiles.

8. The target of claim 6, wherein the edges are inclined plural portions inclined at different angles with respect to the normal to form the gap as a convolute gap extending between the principal surfaces of the tiles.

9. The target of claim 8, wherein the plural portions include a slanted upper portion and a lower portion adjacent the backing plate and joined the upper portion by an intermediate portion extending substantially perpendicular to the normal.

10. The target of claim 9, wherein the lower portion is slanted with respect to normal.

11. The target of claim 9, wherein the lower portion is substantially parallel to the normal.

12. A target source, comprising:
the target of claim 9, wherein the array is a one-dimensional array with the gaps extending along a first direction along the principal surfaces; and
a magnetron comprising a plurality of first magnets of a first magnetic polarity and second magnets of a second magnetic polarity arranged to form a gap between the first and second magnets arranged in a closed serpentine loop having straight portions extending along a second direction perpendicular to the first direction and having rounded portions connecting the straight portions.

13. A method of coating a substrate, comprising the steps of:
placing a substrate within a vacuum chamber in opposition to a sputtering target comprising a plurality of target tiles bonded to a backing plate in an array and having structured edges forming a gap between neighboring ones of the bonded tiles that is at least partially inclined with respect to a normal of principal surfaces of the bonded tiles; and
exciting a plasma within the vacuum chamber to sputter material of the tiles onto the substrates.

14. The method of claim 13, wherein the structured edges are inclined with respect to the normal to form the gap as a gap extending between the principal surfaces which is inclined with respect to the normal.

15. The method of claim 13, wherein the edges include plural portions extending between the principal surfaces at different angles with respect to the normal to thereby form the gap as a convolute gap.

16. The method of claim 15, wherein the plural portions include a lower portion adjacent the backing plate, an upper portion inclined with respect to the normal, and an intermediate portion extending substantially perpendicularly to the normal.

17. The method of claim 16, wherein the lower portion is inclined with respect to the normal.

18. The method of claim 16, wherein the lower portion extends substantially parallel to the normal.

19. The method of claim 15, wherein the array is a one-dimensional array with the gaps extending along a first direction along the principal surfaces and further comprising placing on a side of the backing plate opposite the target a magnetron comprising a plurality of first magnets of a first magnetic polarity and second magnets of a second magnetic polarity arranged to form a gap between the first and second magnets arranged in a closed serpentine loop having straight sections extending along a second direction perpendicular to the first direction and having rounded portions connecting the straight sections.
